(19) United States
(12) Patent Application Publication
(10) Pub. No.: US 2004/0146079 A1
(43) Pub. Date: Jul. 29, 2004

(54) Long wavelength, GaInNAs/GaInAs optical device

(75) Inventor: Seong-Jin Lim, Gyeonggi-do (KR)

Correspondence Address: BURNS DOANE SWECKER & MATHIS L L P, POST OFFICE BOX 1404, ALEXANDRIA, VA, 22313-1404, US

(73) Assignee: SAMSUNG ELECTRONICS CO., LTD., Gyeonggi-do (KR)

(21) Appl. No.: 10/751,958

(22) Filed: Jan. 7, 2004

(30) Foreign Application Priority Data
Jan. 29, 2003 (KR) 2003-5930

(51) Int. Cl. H01S 5/00

(52) U.S. Cl. 372/45

(57) ABSTRACT

An optical device with a GaInNAs/GaInAs structure is provided. The optical device includes a GaInNAs active layer, which has a quantum well structure and produces light; and two GaInAs barrier layers, one of which is deposited on the upper surface of the GaInNAs active layer and the other is deposited on the lower surface of the GaInNAs active layer and which have higher conduction band energy and lower valence band energy than the GaInNAs active layer. Therefore, the optical device has an excellent light emitting property at a long wavelength band of 1.3 μm or more.

### BACKGROUND OF THE INVENTION

This application claims the priority of Korean Patent Application No. 2003-5930, filed on Jan. 29, 2003, in the Korean Intellectual Property Office, the disclosure of which is incorporated herein in its entirety by reference.

1. Field of the Invention

The present invention relates to an optical device having a GaInNAs active layer and more particularly, to a GaInNAs/GaInAs optical device capable of shifting the emission wavelength of light to a long wavelength.

2. Description of the Related Art

Recently, in the field of an optical communication system and data link, there have been studied in developing a laser emitting light of a long wavelength of 1.3 μm or more. A long wavelength laser of 1.3 μm band operates in an optical fiber with minimal dispersion and thus is suitable for high speed communication. A long wavelength laser of 1.5 μm band is transmitted through its minimal absorption and thus is suitable for longer distance communication. A long wavelength laser has a low driving voltage and thus is suitable for a highly integrated, Si-based circuit.

A GaAs substrate-based long wavelength laser currently studied for a local optical communication mainly uses a GaInNAs material as an active layer and a GaAs or GaNAs material as a barrier layer to obtain a wavelength of 1.3 μg or more. The GaAs substrate-based device has advantages such as low cost, simple crystal growth technology, and highly reflective mirror. However, in a case wherein the GaAs or GaNAs barrier layers are formed on the GaAs substrate and then the GaInNAs active layer is sandwiched between the barrier layers, the optical properties of the laser are deteriorated.

Incorporation of nitrogen (N) in a GaInAs layer results in formation of a GaInNAs (also called as Guinness) active layer, thereby increasing a wavelength. However, shift to a long wavelength is very difficult due to low incorporating ratio of N in InGaAs layer with a high indium (In) composition. In addition, as increasing the amount of N to accomplish a long wavelength, the optical properties of GaInNAs active layer tend to be remarkably degraded. Conventionally, in order to enhance the light emitting property of a GaInNAs optical device, a thermal annealing process is used after growth. In this case, discharge of In occurs, and thus, a wavelength of optical device undergoes a shift to a short wavelength. As a result, it is difficult to manufacture a high performance optical device, which has a GaInNAs active layer.

### SUMMARY OF THE INVENTION

The present invention provides a high performance optical device, which emits the light of a long wavelength.

According to an aspect of the present invention, there is provided an optical device comprising: a GaInNAs active layer, which has a quantum well structure and produces light; and two GaInAs barrier layers, one of which is deposited on the upper surface of the GaInNAs active layer and the other is deposited on the lower surface of the GaInNAs active layer, and which have higher conduction band energy and lower valence band energy than the GaInNAs active layer.

The GaInNAs active layer may be made of a GaₓIn₁₋ₓN_{y}As_{1-y} compound where 0≦x≦1 and 0≦y≦1.

The GaInAs barrier layers may be made of a GaₓIn₁₋ₓAs compound where 0≦x≦1.

The GaInNAs active layer may comprise a GaAs substrate on the lower surface thereof.

According to the present invention, by incorporating a new GaInAs barrier layer into a conventional optical device having a GaAs substrate and a GaInNAs active layer, an optical device which emits light of a long wavelength of 1.3 μm or more can be manufactured.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic diagram of a quantum well structure of an optical device according to an embodiment of the present invention;

FIG. 2 is a schematic sectional view of an optical device according to an embodiment of the present invention;

FIG. 3 is a schematic diagram showing a principle of wavelength shift with strain compression in an optical device according to an embodiment of the present invention;

FIG. 4 is a graph showing an increase of a peak wavelength in an optical device according to an embodiment of the present invention;

FIG. 5 is a schematic diagram showing a compensation effect for discharge of indium (In) in an optical device according to an embodiment of the present invention; and

FIG. 6 is a graph showing a change in short wavelength shift of a peak wavelength according to In composition after annealing of an optical device according to an embodiment of the present invention.

### DETAILED DESCRIPTION OF THE INVENTION

Hereinafter, the optical device according to the present invention will be described in detail with reference to the accompanying drawings.

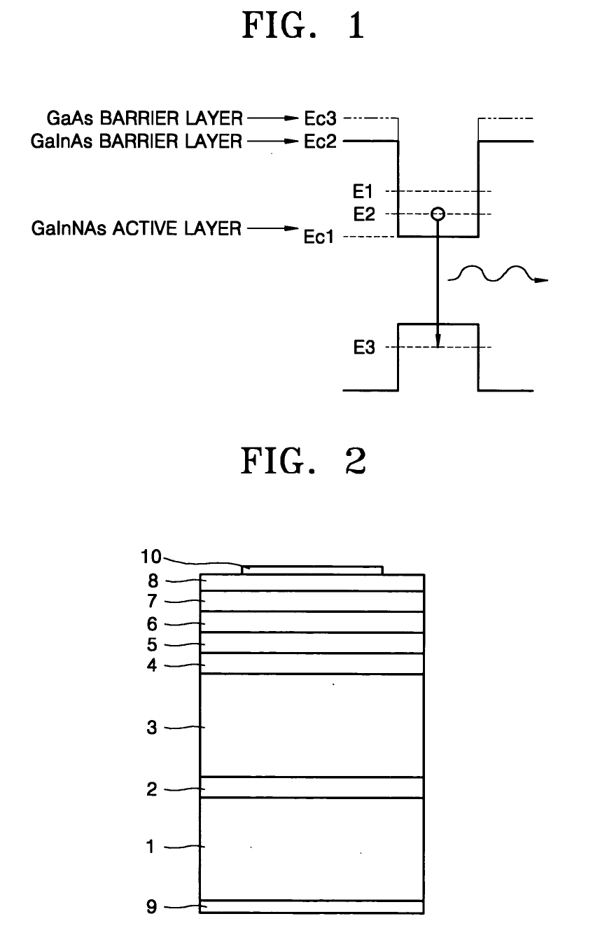

FIG. 1 is a schematic diagram of a quantum well structure of an optical device according to an embodiment of the present invention.

Referring to FIG. 1, a GaInNAs active layer has a quantum well structure with the lowest conduction band energy, Ec1, and a GaInAs barrier layer has a conduction band energy of Ec2, which is higher than Ec1. Ec3, which is denoted as a dotted line, represents a conduction band energy of a GaAs barrier layer. In a conventional, GaInNAs active layer-based optical device, a GaAs material, which has a higher conduction band energy than a GaInAs material, is used for a barrier layer.

An electron trapped in the quantum well structure has a ground state energy of E1 in the laminate structure of the GaAs barrier layer on the GaInNAs active layer, while having a ground state energy of E2 in the laminate structure of the GaInAs barrier layer on the GaInNAs active layer. That is, when the barrier layer is changed from GaAs to GaInAs, the ground state energy of an electron in a quantum well decreases. Thus, when compared to transition of an electron from an E1 level to an E3 level, the emission energy of light decreases in the case of transition of an electron from an E2 level to an E3 level. The emission energy of light (E) must meet with Equation 1 below. It can be seen from the equation 1 that as the emission energy of light (E) decreases, a wavelength (X) shifts to a long wavelength.

E=hc/λ Equation 1

where, h is Planck's constant (6.63×10⁻³⁴J·S) and c is the speed of light (3×10⁸ M/s).

The optical device of the present invention is characterized by having a GaInNAs active layer and two GaInAs barrier layers on the respective upper and lower surfaces of the active layer.

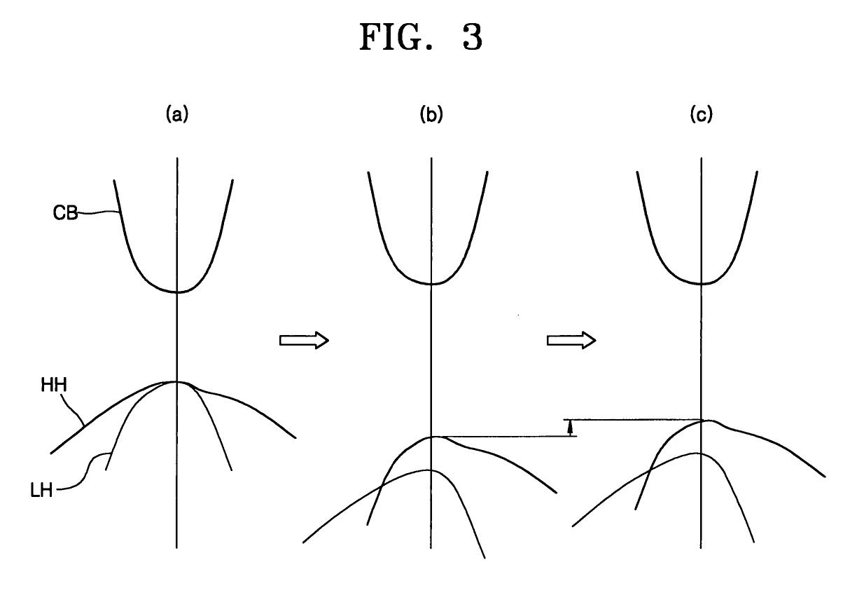

FIG. 2 is a schematic sectional view of an optical device according to an embodiment of the present invention.

Referring to FIG. 2, the optical device of the present invention comprises an n-type GaAs substrate 1, a GaAs buffer layer 2, a n-type cladding semiconductor layer 3 made of a AlGaAs material, a first GaInAs barrier layer 4, a GaInNAs active layer 5, a second GaInAs barrier layer 6, a p-type cladding semiconductor layer 7 made of a AlGaAs material, and a p-type GaAs contact layer 8, which are sequentially deposited on the GaAs substrate 1. An n-type electrode 9 is formed on the lower surface of the GaAs substrate 1 and a p-type electrode 10 is formed on the p-type GaAs contact layer 8.

The optical device of the present invention as shown in FIG. 2 has the GaInNAs active layer 5 and the first and second barrier layers 4 and 6 made of a GaInAs material on the respective upper and lower surfaces of the active layer 5. Therefore, the ground state energy of an electron in the quantum well structure of the active layer 5 can be reduced. An electron from the n-type electrode 8 and a hole from the p-type electrode 9 pass through the first compound semiconductor layer 3 and the second compound semiconductor layer 7, respectively, and then tunnel through the first and second barrier layers 4 and 6, respectively. Then, the electron and the hole recombine with each other in the active layer 5 to thereby emit light. In this case, the conduction band energies of the first and second barrier layers 4 and 6 decrease, when compared to a conventional optical device. As a result, an energy band gap is reduced, thereby the emission wavelength of active layer shifts to a long wavelength.

FIG. 3 is a schematic diagram showing a principle of wavelength shift with strain compression in an optical device according to an embodiment of the present invention.

FIG. 3(a) shows a conduction band (CB) and distribution of a light hole (LH) and a heavy hole (HH) of a valence band energy in a GaInNAs/GaAs structure. This is the case that there is no strain due to lattice matching of GaAs.

A generally used GaInNAs active layer requires somewhat high indium (In) composition in order to secure a long wavelength of 1.3 μm or more. For this, a compressive strain is applied to the GaInNAs active layer, as shown in FIG. 3(b). In such a compressive strain application state, the lattice mismatching of GaAs occurs and the energy levels of the LH and HH decrease. As a result, the band gap between the conduction band energy and the valence band energy increases.

However, in case of using a GaInNAs material for a barrier layer of such a GaInNAs active layer, as shown in FIG. 3(c), GaInAs lowers the compressive strain applied to only the GaInNAs active layer due to its higher lattice constant than GaAs or GaNAs. As a result, an energy band gap decreases, when compared to the case of using a GaAs or GaNAs barrier layer. Therefore, the wavelength of light emitted from the structure having the GaInAs barrier layer/GaInNAs active layer shifts to a long wavelength.

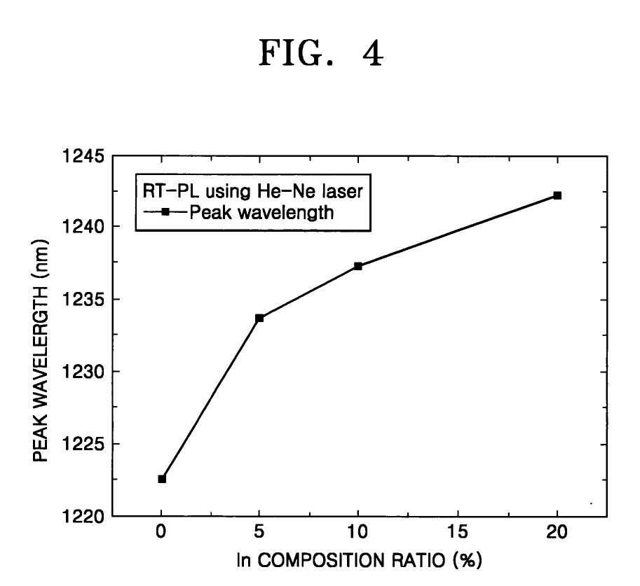

FIG. 4 is a graph showing a shift in a peak wavelength according to an increase of the In composition of a barrier layer in an optical device with the quantum well structure according to an embodiment of the present invention. In this case, a He—Ne laser is used as an excitation light source and the peak wavelength represents a photoluminescence (PL) measurement.

Referring to FIG. 4, the peak wavelength is 1,223 nm in a GaAs barrier layer for a quantum well structure, 1,234 nm in a barrier layer with 5% of the In composition ratio, 1,237 nm in a barrier layer with 10% of the In composition, and 1,243 nm in a barrier layer with 20% of the In composition. That is, in case of a GaInAs barrier layer with a 20% increased In composition, the peak wavelength shifts to a long wavelength by about 20 nm, when compared to a GaAs barrier layer.

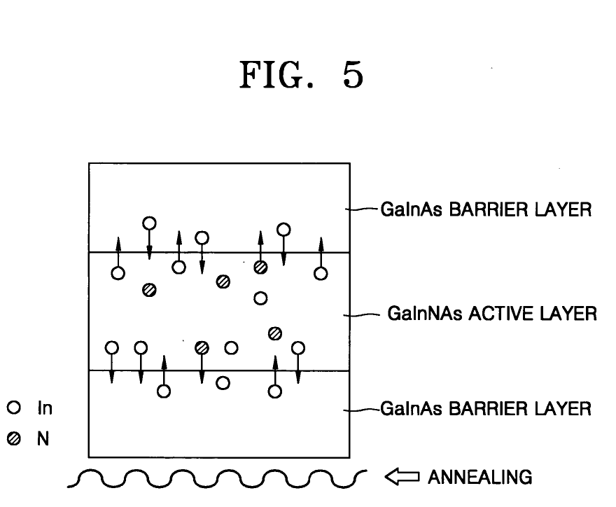

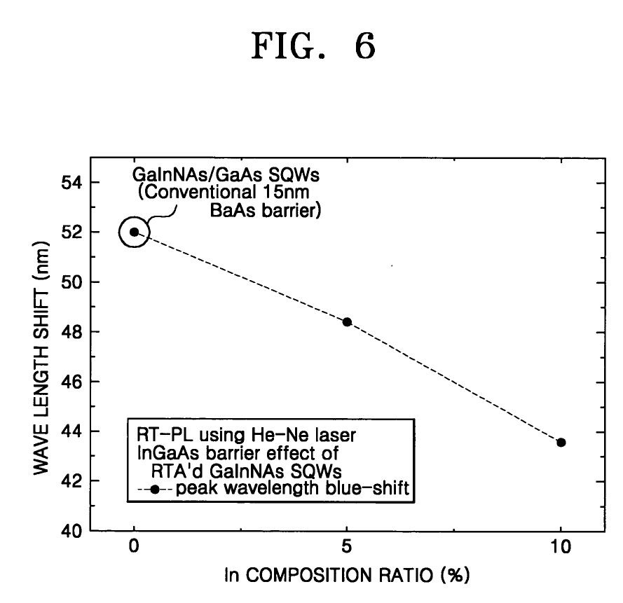

FIG. 5 is a schematic diagram showing a compensation effect for In discharge upon annealing among the manufacturing processes of an optical device according to an embodiment of the present invention.

In a conventional manufacture process of an optical device with a GaInNAs active layer, in order to enhance a light emitting efficiency, which decreases with the incorporation of N, a thermal annealing process is performed. However, during such an annealing process, discharge of In and N from the GaInNAs active layer occurs, which is a major factor for the shift of the emission wavelength of light to a short wavelength. On the other hand, in the case of an optical device with a GaInAs barrier layer of the present invention, upon the annealing, the inner diffusion of In occurs in both the active layer and the barrier layer, thereby compensating the In loss in the active layer. Referring to FIG. 5, while In and N travel from the GaInNAs active layer to the GaInAs barrier layer upon the annealing, In of the GaInAs barrier layer also travels to the GaInNAs active layer to thereby compensate the In loss.

FIG. 6 is a graph showing a change in short wavelength shift of a peak wavelength according to In composition of the GaInAs barrier layer after annealing of an optical device according to an embodiment of the present invention. Here, the used samples are annealed and there is shown a change of peak wavelength before and after the annealing measured by a PL measurement at room temperature using a He—Ne laser as excitation light source.

Referring to FIG. 6, the change in short wavelength shift is 52 nm in 0% of the In composition. When the In composition increases by 5%, the change in short wavelength shift reduces to 48 nm, while when the In composition increases by 10%, the change in short wavelength shift reduces to 44 nm. That is, as the In composition increases, the change in short wavelength shift reduces. Therefore, a long wavelength can be accomplished by reduction of the change in short wavelength shift with increase of the In composition.

As apparent from the above description, the optical device of the present invention comprises a GaInNAs active layer and two GaInAs barrier layers on the respective upper and lower surfaces of the active layer. Therefore, the energy band gap decreases and thus the emission wavelength of light shifts to a long wavelength band. In addition, the strain between the active layer and the barrier layers by the lattice mismatching is reduced, thereby preventing the impediment of light emitting property by the lattice mismatching and an In loss by In discharge upon annealing.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An optical device comprising:
a GaInNAs active layer, which has a quantum well structure and produces light; and
two GaInAs barrier layers, one of which is deposited on the upper surface of the GaInNAs active layer and the other is deposited on the lower surface of the GaInNAs active layer, and which have higher conduction band energy and lower valence band energy than the GaInNAs active layer.

2. The optical device according to claim 1, wherein the GaInNAs active layer is made of a GaₓIn₁₋ₓN_{y}As_{1-y} compound where 0≦x≦1 and 0≦y≦1.

3. The optical device according to claim 1, wherein the GaInAs barrier layers are made of a GaₓIn₁₋ₓAs compound where 0≦x≦1.

4. The optical device according to claim 1, wherein the GaInNAs active layer comprises a GaAs substrate on the lower surface thereof.
